(19) United States
(12) Patent Application Publication
(10) Pub. No.: US 2015/0349395 A1
(43) Pub. Date: Dec. 3, 2015

(54) ISOLATOR/CIRCULATOR WITH IMPROVED LOSS AND BANDWITH

(71) Applicant: Ernesto G.F. Starri, Riverside, CA (US)

(72) Inventor: Ernesto G.F. Starri, Riverside, CA (US)

(21) Appl. No.: 14/725,038

(22) Filed: May 29, 2015

Related U.S. Application Data
(60) Provisional application No. 62/004,272, filed on May 29, 2014.

(51) Int. Cl. H01P 1/32; H03F 3/189; H03F 3/20; H03F 3/68

(52) U.S. Cl. CPC H01P 1/32; H03F 3/68; H03F 3/189; H03F 3/20; H03F 2200/451

(57) ABSTRACT

An isolator/circulator circuit for use in any kind of electronic system wherein reflected signal insertion loss is eliminated or minimized while bandwidth of the system is generally unlimited and limited only by the bandwidth of the amplifiers PA1 and PA2 and by the bandwidth of the divider/combiner X2 and X4, one (1) octave as minimum and several as maximum. The circuit allows this technique to be used in low frequency applications below MHz range where circulator/isolator sizes/cost become prohibitive and physically impossible to fabricate.

### CROSS-REFERENCE TO RELATED APPLICATIONS

This application claims priority from U.S. Provisional Patent Application No. 62/004,272, titled “Isolator/Circulator With Improved Loss And Bandwidth”, which was filed on May 29, 2014 and is incorporated fully herein by reference.

### FIELD OF THE INVENTION

The present invention relates generally to radio frequency (RF) components and circuits and more particularly, to a circuit for replacing an isolator/circulator in a circuit avoiding the loss and limited bandwidth of typical isolators/circulators.

### BACKGROUND OF THE INVENTION

When utilizing an amplifier in a radio frequency (RF) circuit, it is important to protect the amplifier or other output power device from reflected power. This is typically done with a device or circuit called an RF isolator. An isolator is a non-reciprocal device, with a non-symmetric scattering matrix. An ideal isolator transmits all the power entering port 1 to port 2, while absorbing all the power entering port 2. An RF Isolator is often a two-port ferromagnetic passive device which is used to protect other RF components from excessive signal reflection. An RF circulator is a three-port ferromagnetic passive device used to control the direction of signal flow in a circuit and is a very cost effective solution, but it has limitation of bandwidth and high insertion losses.

An important consideration when specifying an isolator or circulator is to ensure the device has adequate isolation for the given application. For example, in a RF transmission system, it is important to protect the amplifier from reflected power which might be received by means of imperfect impedance matching at the end of the transmission line i.e. from the load. Isolation is a unit of measure (in dB) that states the separation of signal levels on adjacent ports of a device. The greater the isolation value, the less interference from a signal on one port is present at the other. The amount of isolation is directly affected by the VSWR presented at port 3 of the isolator. If the match on port 3 is poor, isolation below 10 dB can be expected, but if the match is improved to 1.10:1 by using a good termination device in the circuit, then the isolation would improve to over 20 dB. VSWR (Voltage Standing Wave Ratio), is a measure of how efficiently radio-frequency power is transmitted from a power source, through a transmission line, into a load (for example, from a power amplifier through a transmission line, to an antenna).

Another important consideration when specifying circulators and isolators is to ensure the device has minimal insertion loss when inserted in a transmission path. Generally, the insertion loss of a circulator/isolator (or any microwave device) becomes more significant at higher frequency, and at higher than normal bandwidth, namely because insertion loss increases with frequency and increased bandwidth require the combination of more than one circulator/isolator. Up to 1 dB of power loss is not uncommon. Accordingly, the criteria of low insertion loss will prevent precious power from being wasted.

Accordingly, what is needed is and isolator/circulator which avoids the insertion loss of the prior art devices and the limited band with afforded by those prior art devices.

### SUMMARY OF THE INVENTION

The invention is directed to an alternative solution to a standard isolator/circulator circuit that comprises an analog input signal receiving port (12) as well as a divider (X2). The divider (12) is coupled to the analog input signal receiving port (12) and configured for providing first and second analog divider outputs (11a, 11b) in response to an analog input signal received on the analog input signal receiving port (12). The first and second analog divider outputs (11a, 11b) each have a phase that is shifted 90 degrees in phase relative to one another.

A first phase shifter (X3) is coupled to the second output (11b) of the divider (X2) and to a reflected output signal port (RFL) (16). The first phase shifter (X3) is configured for varying a phase of the second output (11b) of the divider (X2) and the reflected output signal (16), and for providing a directly proportional phase variation signal (13) to a second amplifier PA2.

Also provided is a delay element X1 that is coupled to the first output (11a) of the divider X2, and configured for providing or introducing a delay to a first output signal (15) provided by the first output (11a) of the divider X2. The delay is of a predetermined period of time corresponding to a period of time of delay introduced by the first phase shifter (X3) to the second output (11b) of the divider X2 when the first phase shifter (X3) phase shift is ZERO, and for providing an output signal (15) to a first amplifier PA1.

The circuit includes combiner X4, coupled to the output (13, 15) of each of the first and said second amplifiers (PA1 and PA2), and configured for providing first and second combiner outputs (17, 19). The first and second combiner outputs (17, 19) are shifted 90 degrees in phase relative to one another.

The invention is not intended to be limited to a device or method which must satisfy one or more of any stated or implied objects or features of the invention and should not be limited to the preferred, exemplary, or primary embodiment(s) described herein. Modifications and substitutions by one of ordinary skill in the art are considered to be within the scope of the present invention.

### BRIEF DESCRIPTION OF THE DRAWINGS

These and other features and advantages of the present invention will be better understood by reading the following detailed description, taken together with the drawings wherein:

FIG. 1 is a circuit diagram illustrating the isolator/circulator circuit according to the present invention.

### DETAILED DESCRIPTION OF THE INVENTION

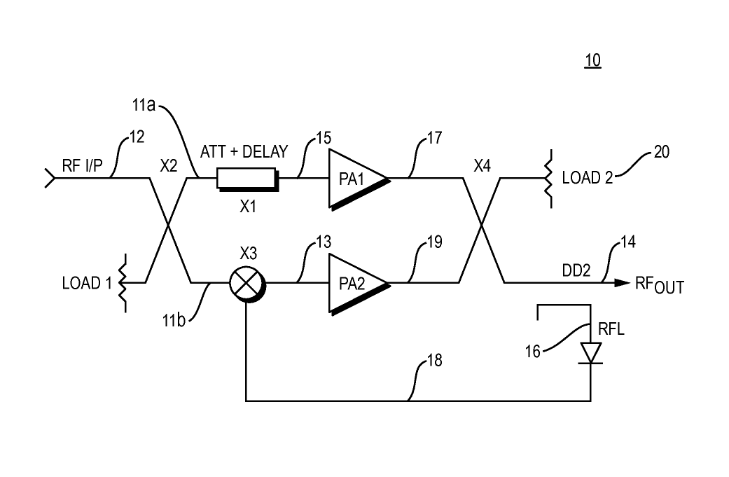

The alternative isolator/circulator circuit 10, FIG. 1, according to the invention is designed to replace the prior art lossy circuits with one that has little to no insertion loss and nearly unlimited bandwidth. The current invention may be used in and with any system needing such a circuit and functionality. The circuit is designed to receive an RF input signal at 12 and provide the RF output signal at the RF output (DD2) 14 to a device such as an antenna. However, the present invention is designed to deal with and adjust for a reflected signal 18 which may be present on the reflected port 16 of the output port DD2.

When the signal present on the reflected port 16 of DD2 progressively increases, then the rectified reflected signal 18 is provided to phase shifter X3 wherein the phase of the input of amplifier PA2 (the rectified reflected signal 18) is progressively changed until the combined output power of PA1 and PA2 (via combiner X4) will be 180 degrees different in phase, and wherein the processed reflected signal 18 which may be present on the reflected port 16 of the output port DD2 is then directed to LOAD 2 20 instead of RF out 14, thus essentially eliminating the effects of the reflected signal 18 received on the reflected port 16. X3 can be any type of phase shifter element providing at least 180 degrees variation (phase shift) either analog or in steps or any other type of broadband phase shifter and the rectified reflected signal 18 from RFL port 16 can then control the phase shift at X3. X1 provides a group delay equal to the inherent group delay of X3 when its phase shift is 0. X2 and X4 can be a 90 degree hybrid divider/combiner or all pass divider/combiners or 0/180 degrees divider/combiners providing a balancing resistor LOAD 2 is always present.

Accordingly, the present invention provides a novel alternative isolator/circulator for use in any kind of system or in insertion loss is eliminated or minimized while bandwidth of the system is generally unlimited and limited only by the bandwidth of the amplifiers PA1 and PA2 and by the bandwidth of the divider/combiner X2 and X4, with one (1) octave as a minimum and several as a maximum, far in excess of what is achievable with the previous ferromagnetic art which can only provide at best only about ⅓rd of an octave. The present invention also allows this technique to be used in low frequency applications (i.e. 2 to 30 MHz range) where circulator/isolator sizes/cost become prohibitive and generally physically impossible to fabricate.

As stated above, the present invention is not intended to be limited to a device or method which must satisfy one or more of any stated or implied objects or features of the invention and should not be limited to the preferred, exemplary, or primary embodiment(s) described herein.

Modifications and substitutions by one of ordinary skill in the art are considered to be within the scope of the present invention, which is not to be limited except by the allowed claims and their legal equivalents.

What is claimed is:

1. An isolator/circulator circuit, comprising:
an analog input signal receiving port, configured for receiving an analog input signal;
a divider element, electrically coupled to said analog input signal receiving port and configured for providing first and second analog divider output signals in response to said analog input signal received on said analog input signal receiving port, wherein said first and second analog divider output signals each have a phase that is shifted 90 degrees in phase relative to one another;
a first phase shifter, said first phase shifter X3 electrically coupled to said second analog divider output of said divider element and to a reflected output signal received from a reflected output signal port, said first phase shifter configured for varying a phase of said second analog divider output of said divider element and said reflected output signal, and for providing a directly proportional phase variation signal to a second amplifier PA2;
a delay element X1, electrically coupled to said first analog divider output of said divider element, and configured for providing a delay to said first analog divider output signal, said delay comprising of a predetermined period of time corresponding to a period of time delay introduced by said first phase shifter to said second analog divider output signal of said divider element when said first phase shifter phase shift is ZERO, and for providing an output signal to a first amplifier; and
a combiner, electrically coupled to said outputs of each of said first and said second amplifiers, and configured for providing first and second combiner outputs, wherein said first and second combiner outputs (17, 19) are shifted 180 degrees in phase relative to one another, wherein said first combiner output is provided to an RF output port and wherein said second combiner output is provided to a load element.
